(19) United States
(12) Patent Application Publication
(10) Pub. No.: US 2024/0324364 A1
(43) Pub. Date: Sep. 26, 2024

(54) DISPLAY APPARATUS

(71) Applicant: Samsung Display Co., LTD., Yongin-si (KR)

(72) Inventors: Dongchul SHIN, Yongin-si (KR); Gana KIM, Yongin-si (KR); Jangyeol YOON, Yongin-si (KR)

(21) Appl. No.: 18/610,720

(22) Filed: Mar. 20, 2024

(30) Foreign Application Priority Data
Mar. 24, 2023 (KR) 10-2023-0039020
Apr. 28, 2023 (KR) 10-2023-0056579

(51) Int. Cl. H10K 59/131; H10K 59/35; H10K 102/00

(52) U.S. Cl. CPC H10K 59/131; H10K 59/353; H10K 2102/311

(57) ABSTRACT

A display apparatus includes: a display panel including, in a top-plan view, a first display area and one or more second display areas surrounded by the first display area, where the one or more second display areas are stretchable, and each of the one or more second display areas includes a first stretchable area having a constant stretching rate and a second stretchable area surrounding the first stretchable area and having a stretching rate that decreases away from a center of the first stretchable area.

This application claims priority to Korean Patent Application No. 10-2023-0039020, filed on Mar. 24, 2023, and Korean Patent Application No. 10-2023-0056579 filed on Apr. 28, 2023, and all the benefits accruing therefrom under 35 U.S.C. § 119, the contents of which in their entirety are herein incorporated by reference.

### BACKGROUND

### 1. Field

One or more embodiments relate to a display apparatus, and more particularly, to a display apparatus that is at least partially stretchable.

### 2. Description of the Related Art

Due to the development of display devices for displaying electrical images in a visual manner, various display devices having excellent characteristics, such as thinning, light weight, and low power-consumption, have been introduced.

For example, there have been active research and development on flexible display devices that may be bent from a flat state by a certain angle and/or stretchable display devices that may be stretched into various shapes.

### SUMMARY

One or more embodiments provide a structure of a display apparatus that is at least partially stretchable.

However, this is only an example, and the technical goals to be achieved by the disclosure are not limited thereto.

Additional aspects will be set forth in part in the description which follows and, in part, will be apparent from the description, or may be learned by practice of the presented embodiments of the disclosure.

According to one or more embodiments, a display apparatus includes: a display panel including, in a top-plan view, a first display area and one or more second display areas surrounded by the first display area, where the one or more second display areas are stretchable, and the second display area includes a first stretchable area having a constant stretching rate and a second stretchable area surrounding the first stretchable area and having a stretching rate decreasing away from a center of the first stretchable area.

In an embodiment, the display panel may include, in the second display area, island portions apart from one another, connectors connecting the island portions to one another, and openings surrounded and defined by the island portions and the connectors.

In an embodiment, a subpixel configured to emit at least one of red light, blue light, and green light may be arranged in each of the island portions.

In an embodiment, in the first stretchable area, widths of the openings may be identical to one another.

In an embodiment, in the second stretchable area, widths of the openings may be different from one another.

In an embodiment, in the second stretchable area, widths of the openings may decrease away from a center of the first stretchable area.

In an embodiment, in a top-plan view, the second stretchable area may have a closed-loop shape.

In an embodiment, the one or more second display areas may be arranged in parallel in a first direction.

In an embodiment, the display apparatus may further include a board layer disposed under the display panel, and the board layer may include a convex portion overlapping the second display area and protruding in a convex manner toward the display panel in a top-plan view.

In an embodiment, the board layer may be arranged apart from the display panel in a thickness direction.

In an embodiment, the display apparatus may further include a gap supporter surrounding the convex portion in a top-plan view and filling a gap between the display panel and the board layer.

In an embodiment, the convex portion may be arranged such that an outer circumference of the convex portion may be within an outer circumference of the first stretchable area in a top-plan view.

In an embodiment, the display apparatus may further include an anti-friction layer disposed between the display panel and the board layer.

In an embodiment, the display apparatus may further include a first cover film layer disposed on the display panel, and the first cover film layer may include a first film portion having a first modulus and arranged to overlap the second display area in a top-plan view and a second film portion having a second modulus and arranged to surround the first film portion in a top-plan view.

In an embodiment, the first modulus of the first film portion may be less than the second modulus of the second film portion.

In an embodiment, the display apparatus may further include a board layer disposed under the display panel, wherein the board layer may include a convex portion overlapping the second display area and protruding in a convex manner toward the display panel in a top-plan view, and in a top-plan view, an outer circumference of the first film portion may be between the outer circumference of the first stretchable area and the outer circumference of the convex portion.

In an embodiment, the display apparatus may further include a second cover film disposed between the first cover film layer and the display panel and the second modulus may be the same as the first modulus, and the second cover film and the first film portion may be monolithic.

In an embodiment, the display apparatus may further include a third cover film layer disposed on the first cover film layer and having the first modulus, the third cover film layer and the first film portion may be monolithic, and a cover film layer be defined to include the first cover film layer, the second cover film layer, and the third cover film layer.

In an embodiment, an outer circumference of the first film portion may be tapered to decrease toward a top of the cover film layer.

In an embodiment, an end of the second film portion, defining an outer circumference of the first film portion, may be bent toward the top of the cover film layer in a thickness direction.

Other aspects, features, and advantages in addition to the descriptions will be apparent from detailed descriptions, claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment of the disclosure;

FIG. 2 is an equivalent circuit diagram schematically illustrating a light-emitting diode of the display apparatus and a subpixel circuit electrically connected to the light-emitting diode, according to an embodiment of the disclosure;

FIG. 3 is a cross-sectional view of a portion of the display apparatus taken along line III-III′ shown in FIG. 1, according to an embodiment of the disclosure;

FIG. 4 is a top-plan view schematically illustrating an enlarged image of a region IV of the display apparatus in FIG. 1, according to an embodiment of the disclosure;

FIG. 5 is a top-plan view schematically illustrating a first stretchable area of an enlarged image of a region V shown in FIG. 4, according to an embodiment of the disclosure;

FIG. 6 is a top-plan view schematically illustrating a second stretchable area of an enlarged image of a region VI shown in FIG. 4, according to an embodiment of the disclosure;

FIG. 7 is a cross-sectional view of a portion of the display apparatus taken along line VII-VII′ shown in FIG. 5, according to an embodiment of the disclosure;

FIG. 8 is a cross-sectional view schematically illustrating a portion of a display apparatus according to an embodiment of the disclosure;

FIG. 9 is a cross-sectional view schematically illustrating a portion of the display apparatus of FIG. 8 according to an embodiment of the disclosure; and

FIGS. 10 to 12 are each a cross-sectional view schematically illustrating a cover film layer according to an embodiment of the disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As used herein, the terms ‘first’, ‘second’ are only used to distinguish one element from another, not in a limited sense.

As used herein, the singular forms are intended to encompass the plural forms as well, unless the context clearly indicates otherwise.

It will be further understood that the terms “comprise,” “comprising,” “include,” “including,” “have,” “having,” and the like, when used herein, specify the presence of stated features and/or elements, but do not preclude the presence or addition of one or more other features and/or elements.

In the following embodiments, when a portion such as a film, an area, or a component is on or above another portion, the portion may be directly on the other portion, or other films, areas, or components may be located therebetween.

In the drawings, the sizes of elements may be exaggerated or reduced for convenience of description. For example, since the size and thickness of each element is arbitrarily shown in the drawings for convenience of description, the disclosure is not necessarily limited to those illustrated.

When some embodiments may be differently implemented, a particular process sequence may be performed differently from a sequence described. For example, two processes described in succession may be performed substantially simultaneously, or may be performed in an order opposite to an order described.

In the present specification, when it is referred that a film, an area, and a component are connected to another film, area, and component, the film, area, and component may be directly connected to the other film, area, and component, or may be indirectly connected with another film, area, and component therebetween. For example, when it is referred that a film, an area, and a component are electrically connected to another film, area, and component, the film, area, and component may be directly in electric connection with the other film, area, and component, or may be indirectly in electric connection with the other film, area, and component with another film, area, and component therebetween.

An x-axis, a y-axis, and a z-axis are not limited to three axes on an orthogonal coordinate system, and may be interpreted as a wide meaning including the same. For example, the x-axis, y-axis, and z-axis may be orthogonal to one another, but may also refer to different directions that are not orthogonal to one another.

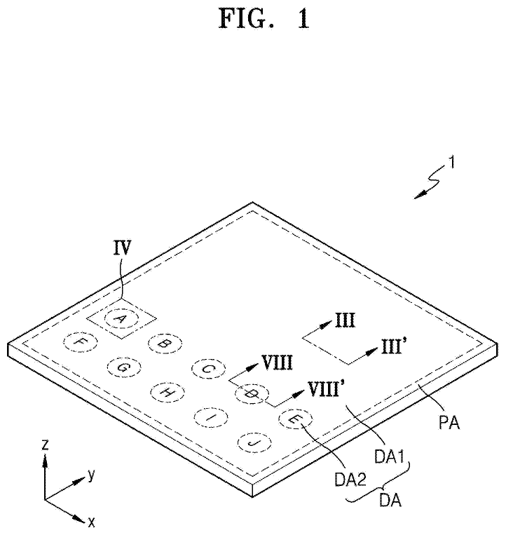

FIG. 1 is a perspective view schematically illustrating a display apparatus 1 according to an embodiment of the disclosure.

Referring to FIG. 1, the display apparatus 1, which is an apparatus configured to display videos or still images, may be used for various products such as mobile phones, smart phones, tablet personal computers, mobile communication terminals, electronic handbooks, electronic books, portable multimedia players, navigation systems, ultra mobile PCs, televisions, notebooks, monitors, billboard charts, Internet of things (“IoT”), and the like. In addition, the display apparatus 1 according to an embodiment may be used for wearable devices such as smart watches, watch phones, and head mounted displays (“HMD”). The display apparatus 1 according to an embodiment may include a center information display (“CID”) arranged on a dashboard or a center fascia of a vehicle, may include a room mirror display substituting a side mirror of a vehicle, and may be used as a display screen arranged on a back surface of a front seat as entertainment for passengers in rear seats of a vehicle.

The display apparatus 1 may have an approximately rectangular shape, as shown in FIG. 1. For example, as shown in FIG. 1, the display apparatus 1 may have a planar shape that is generally rectangular having a short side extending in a first direction (e.g., a x direction or a −x direction) and a long side extending in a second direction (e.g., a y direction or a −y direction). In an embodiment, a point at which the short side extending in the first direction (e.g., the x direction or the −x direction) and the long side extending in the second direction (e.g., the y direction or the −y direction) meet each other may have the form of a right angle or may have a round shape having a certain curvature. However, the planar shape of the display apparatus 1 is not limited to a rectangle and may have other shapes such as a polygon, a circle, or an oval.

In addition, although not shown, the display apparatus 1 may also have a structure of being folded with reference to a folding axis (not shown). For example, the display apparatus 1 may be folded to maintain a certain angle or may be completely folded with reference to a folding axis crossing a center of the display apparatus 1 in the first direction (e.g., the x direction or the −x direction). Hereinafter, for convenience of explanation, a case in which the display apparatus 1 has a flat structure will be mainly described.

The display apparatus 1 may include a display area DA and a peripheral area PA. The display area DA may be configured to display images. In this case, pixels may be arranged in the display area DA. The display apparatus 1 may be configured to provide images using light emitted from the pixels. Each pixel may be configured to emit light using a display element. In an embodiment, each pixel may be configured to emit at least one of red light, green light, and blue light. That is, the pixel may include a red subpixel configured to emit red light, a green subpixel configured to emit green light, and a blue subpixel configured to emit blue light.

The display area DA may include a first display area DA1 and a second display area DA2. The first display area DA1 may correspond to most of the display area DA. The first display area DA1 may include a rigid area that is not stretchable. In other words, as to be described later, the first display area DA1 may be considered as an area that does not include openings defined among the pixels.

The second display area DA2, which is an area surrounded by the first display area DA1, may be provided in the number equal to or greater than one. The second display area DA2 may include a stretchable area. In other words, as to be describe later, the second display area DA2 may be considered as an area including openings defined among the pixels. In an embodiment, the second display area DA2 may include an area in which a keyboard for inputting texts is displayed. In this case, the second display area DA2 may be provided in a plurality, and each of the plurality of second display areas DA2 may be configured to display one or more letters for inputting texts. In an embodiment, the plurality of second display areas DA2 may be arranged in parallel in the first direction (e.g., the x direction), but is not limited thereto and may be arranged in different manners, e.g., in a zigzag manner in another embodiment.

The peripheral area PA, which does not provide images, may include a non-display area. The peripheral area PA may at least partially surround the display area DA. For example, the peripheral area PA may generally surround the display area DA. A driver configured to provide electrical signals to the pixels, a power wiring configured to provide power, and the like may be arranged in the peripheral area PA. For example, a scan driver configured to apply a scan signal to the pixels may be arranged in the peripheral area PA. In addition, a data driver configured to apply a data signal to the pixels may be arranged in the peripheral area PA.

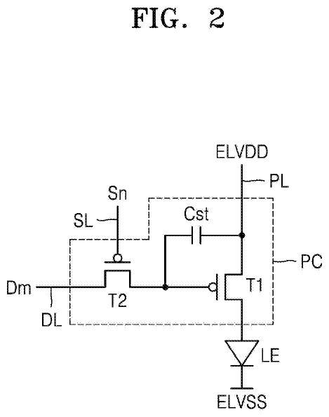

FIG. 2 is an equivalent circuit diagram schematically illustrating any one light-emitting diode of the display apparatus 1 according to an embodiment of the disclosure and a subpixel circuit PC electrically connected to the light-emitting diode.

Referring to FIG. 2, the subpixel circuit PC electrically connected to the light-emitting diode LE may include a driving transistor T1, a switching transistor T2, and a storage capacitor Cst.

The switching transistor T2 may be connected to a scan line SL and a data line DL, and may be configured to deliver a data signal Dm input from the data line DL to the driving transistor T1, in response to a scan signal Sn input from the scan line SL.

The storage capacitor Cst may be connected to the switching transistor T2 and a driving voltage line PL, and may be configured to store a voltage corresponding to a difference between the voltage delivered from the switching transistor T2 and a first power voltage ELVDD provided to the driving voltage line PL.

The driving transistor T1 may be connected to the driving voltage line PL and the storage capacitor Cst, and may be configured to control a driving current flowing from the driving voltage line PL through the light-emitting diode LE to correspond to a value of the voltage stored in the storage capacitor Cst. The light-emitting diode LE may be configured to emit light having certain luminance in response to the driving current. A counter electrode (e.g., a cathode) of the light-emitting diode LE may receive a second power voltage ELVSS.

Although FIG. 2 illustrates that the subpixel circuit PC includes two transistors and one storage capacitor, in another embodiment, the subpixel circuit PC may include three or more transistors.

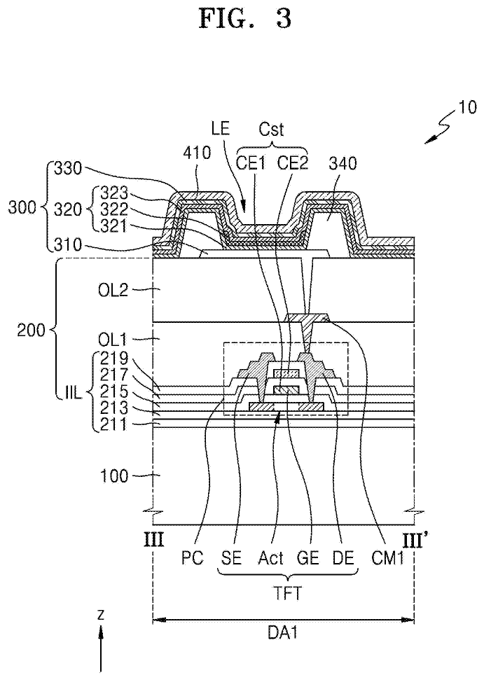

FIG. 3 is a cross-sectional view of a portion of the display apparatus 1 according to an embodiment of the disclosure, taken along line III-III′ shown in FIG. 1. For convenience of explanation, FIG. 3 illustrates a display panel 10 of the display apparatus 1, and hereinafter, a cross-section of the display panel 10 will be mainly described.

Referring to FIG. 3, the display apparatus 1 may include a display panel 10. The display panel 10 may include a substrate 100, a circuit layer 200, and a light-emitting diode layer 300.

The substrate 100 may include a high-molecular resin such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may include a multiple-layer structure including a base layer including the aforementioned high-molecular resin and a barrier layer including an inorganic insulating material. The substrate 100 including a high-molecular resin may be flexible, rollable, and bendable. In some embodiments, the substrate 100 may include glass.

The circuit layer 200 may be disposed on the substrate 100. The circuit layer 200 may include the subpixel circuit PC, an inorganic insulating layer IIL, a first organic insulating layer OL1, a second organic insulating layer OL2, and a first contact electrode CM1. The subpixel circuit PC may include a transistor TFT and the storage capacitor Cst. The transistor TFT may include a semiconductor layer Act, a gate electrode GE, a source electrode SE, and a drain electrode DE. The storage capacitor Cst may include a first capacitor electrode CE1 and a second capacitor electrode CE2.

The inorganic insulating layer IIL may be disposed on the substrate 100. The inorganic insulating layer IIL may include a barrier layer 211, a buffer layer 213, a first gate insulating layer 215, a second gate insulating layer 217, and an interlayer-insulating layer 219.

The barrier layer 211 may be disposed on the substrate 100. The barrier layer 211 may include a layer preventing or reducing permeation of impurities from outside. The barrier layer 211 may include a single layer or multiple layers including an inorganic material such as silicon nitride, silicon oxide, and/or silicon oxynitride.

The buffer layer 213 may be disposed on the barrier layer 211. The buffer layer 213 may include a single layer or multiple layers including an inorganic material such as silicon nitride, silicon oxide, and/or silicon oxynitride.

The semiconductor layer Act may be disposed on the buffer layer 213. The semiconductor layer Act may include polysilicon. Alternatively, the semiconductor layer Act may include amorphous silicon, an oxide semiconductor, or an organic semiconductor. In an embodiment, the semiconductor layer Act may include: a channel area; and a source area and a drain area arranged at opposite sides of the channel area, respectively.

The first gate insulating layer 215 may be disposed on the semiconductor layer Act and the buffer layer 213. The first gate insulating layer 215 may include an inorganic insulating material such as silicon oxide, silicon nitride, silicon oxynitride, aluminum oxide, titanium oxide, tantalum oxide, hafnium oxide, or zinc oxide. The zinc oxide may include zinc oxide (ZnO) and/or zinc peroxide (ZnO₂).

The gate electrode GE may be disposed on the first gate insulating layer 215. The gate electrode GE may overlap the channel area of the semiconductor layer Act in a top-plan view. The gate electrode GE may include a low-resistance metal material. In an embodiment, the gate electrode GE may include a conductive material including molybdenum (Mo), aluminum (Al), copper (Cu), titanium (Ti), and the like, and may include multiple layers or a single layer including the aforementioned materials.

The second gate insulating layer 217 may be disposed on the gate electrode GE and the first gate insulating layer 215. The second gate insulating layer 217 may include an inorganic insulating material such as silicon nitride, silicon oxide, and/or silicon oxynitride.

The second capacitor electrode CE2 may be disposed on the second gate insulating layer 217. The second capacitor electrode CE2 may overlap the gate electrode GE in a top-plan view. In this case, the gate electrode GE may function as the first capacitor electrode CE1. Although FIG. 3 illustrates that the storage capacitor Cst and the transistor TFT overlap each other in a top-plan view, in another embodiment, the storage capacitor Cst and the transistor TFT may not overlap each other in a top-plan view. In this case, the first capacitor electrode CE1 and the gate electrode GE may be separate electrodes. The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or multiple layers including the aforementioned materials.

The interlayer-insulating layer 219 may be disposed on the second capacitor electrode CE2 and the second gate insulating layer 217. The interlayer-insulating layer 219 may include an inorganic insulating material such as silicon oxide, silicon nitride, silicon oxynitride, and the like.

The source electrode SE and the drain electrode DE may each be disposed on the interlayer-insulating layer 219. The source electrode SE and the drain electrode DE may each be connected to the semiconductor layer Act through contact holes provided in the first gate insulating layer 215, the second gate insulating layer 217, and the interlayer-insulating layer 219. At least one of the source electrode SE and the drain electrode DE may include a conductive material including Mo, Al, Cu, and Ti, and may be provided as multiple layers or a single layer including the aforementioned materials. In an embodiment, at least one of the source electrode SE and the drain electrode DE may include a multiple-layer structure including Ti/Al/Ti.

The first organic insulating layer OL1 may be disposed on the inorganic insulating layer IIL, the source electrode SE, and the drain electrode DE. The first organic insulating layer OL1 may include an organic material. The first organic insulating layer OL1 may include an organic insulating material, e.g., a general-purpose polymer such as polymethylmethacrylate (“PMMA”) or polystyrene (“PS”), a polymer derivative having a phenolic group, an acryl-based polymer, an imide-based polymer, an aryl ether-based polymer, an amide-based polymer, a fluoride-based polymer, a p-xylene-based polymer, a vinyl alcohol-based polymer, and a blend thereof.

The first contact electrode CM1 may be disposed on the first organic insulating layer OL1. The first contact electrode CM1 may be electrically connected to the subpixel circuit PC through a contact hole in the first organic insulating layer OL1. The first contact electrode CM1 may include a conductive material including Mo, Al, Cu, Ti, and may include multiple layers or a single layer including the aforementioned materials. The first contact electrode CM1 may include a multiple-layer structure including Ti/Al/Ti.

The second organic insulating layer OL2 may be disposed on the first organic insulating layer OL1 and the first contact electrode CM1. The second organic insulating layer OL2 may include an organic material. The second organic insulating layer OL2 may include an organic insulating material, e.g., a general-purpose polymer such as PMMA or PS, a polymer derivative having a phenolic group, an acryl-based polymer, an imide-based polymer, an aryl ether-based polymer, an amide-based polymer, a fluoride-based polymer, a p-xylene-based polymer, a vinyl alcohol-based polymer, and a blend thereof.

The light-emitting diode layer 300 may be disposed on the circuit layer 200. The light-emitting diode layer 300 may include the light-emitting diode LE and a bank layer 340. The light-emitting diode LE may include an organic light-emitting diode. The light-emitting diode LE may include a first electrode 310, an intermediate layer 320, and a second electrode 330 that is a counter electrode.

The first electrode 310 of the light-emitting diode LE may be electrically connected to the first contact electrode CM1 through a contact hole in the second organic insulating layer OL2. The first electrode 310 may include a conductive oxide, e.g., indium tin oxide (“ITO”), indium zinc oxide (“IZO”), zinc oxide (ZnO), indium oxide (In₂O₃), indium gallium oxide (“IGO”), aluminum zinc oxide (“AZO”). In another embodiment, the first electrode 310 may include a reflective film including Ag, Mg, Al, Pt, Pd, Au, Ni, Nd, Ir, Cr, or a compound thereof. In another embodiment, the first electrode 310 may further include a film including ITO, IZO, ZnO, or In₂O₃ on/under the aforementioned reflective film.

The bank layer 340 may cover a rim of the first electrode 310. The bank layer 340 may include an emission opening, and the emission opening may overlap the first electrode 310 in a top-plan view. The emission opening may define an emission area of light emitted from the light-emitting diode LE. The bank layer 340 may include an organic insulating material and/or an inorganic insulating material. In some embodiments, the bank layer 340 may include a light-blocking material.

Although not shown, a spacer may be disposed on the bank layer 340. In a method of manufacturing the display panel 10, a mask sheet may be used, and in this case, the mask sheet may enter an opening of the bank layer 340 or may be attached to the bank layer 340. The spacer may prevent defects such as damage or breakage of the substrate 100 and a portion of a multiple-layer film on the substrate 100 due to the mask sheet when a deposition material is deposited on the substrate 100. The spacer may include an organic material such as polyimide. Alternatively, the spacer may include an inorganic insulating material such as silicon nitride (SiNₓ) or silicon oxide (SiO₂), or may include an organic insulating material and an inorganic insulating material.

The intermediate layer 320 may be disposed on the first electrode 310 and the bank layer 340. The intermediate layer 320 may include an emission layer 322. The emission layer 322 may overlap the first electrode 310 in a top-plan view. The emission layer 322 may include a high-molecular or low-molecular material emitting light of certain colors.

The intermediate layer 320 may further include a first function layer 321 and/or a second function layer 323. The first function layer 321 may be disposed between the first function layer 321 and the emission layer 322. The first function layer 321 may include a hole transport layer (“HTL”) and/or a hole injection layer (“HIL”). The second function layer 323 may be disposed between the emission layer 322 and the second electrode 330. The second function layer 323 may include an electron transport layer (“ETL”) and/or an electron injection layer (“EIL”). In an embodiment, the first function layer 321 and the second function layer 323 may generally overlap an entire surface of the substrate 100 in a top-plan view.

The second electrode 330 may be disposed on the intermediate layer 320. The second electrode 330 may include a conductive material having a small work function. For example, the second electrode 330 may include a (semi) transparent layer including Ag, Mg, Al, Pt, Pd, Au, Ni, Nd, Ir, Cr, Li, Ca, or alloys thereof. Alternatively, the second electrode 330 may further include a layer including ITO, IZO, ZnO, and In₂O₃ on the (semi) transparent layer including the aforementioned material.

An inorganic encapsulation layer 410 may be disposed on the light-emitting diode layer 300. The inorganic encapsulation layer 410 may generally cover the substrate 100. The inorganic encapsulation layer 410 may include at least one inorganic material from among Al₂O₃, TiO₂, Ta₂O₅, HfO₂, ZnO₂, SiO₂, SiNₓ, and SiON. In some embodiments, an organic encapsulation layer may be disposed on the inorganic encapsulation layer 410. Furthermore, additional inorganic encapsulation layers may be further disposed on the organic encapsulation layer.

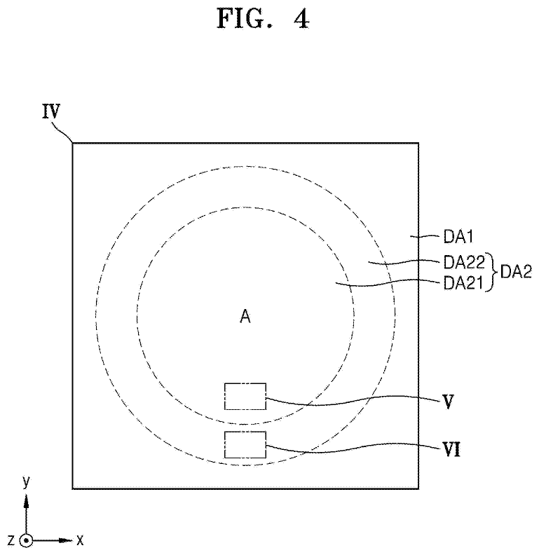

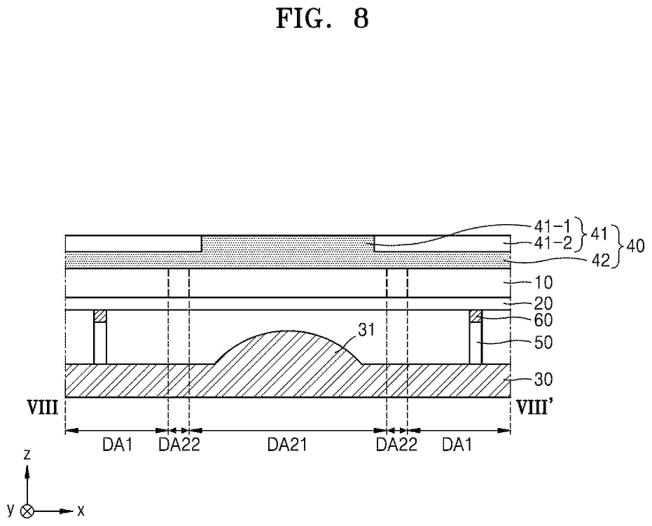

FIG. 4 is a top-plan view schematically illustrating a portion of the display apparatus 1 according to an embodiment of the disclosure, illustrating an enlarged image of a region IV shown in FIG. 1. For convenience of explanation, the display panel 10 of the display apparatus 1 will be mainly described with reference to FIG. 4. As used herein, the “top-plan view” is a view in a thickness direction (e.g., a z direction shown in FIG. 8) of the display panel 10.

Referring to FIG. 4, the second display area DA2 may include an area surrounded by the first display area DA1. As described above, the first display area DA1 may include a rigid area, and the second display area DA2 may include a stretchable (elongatable) area. In an embodiment, the second display area DA2 may have a circular shape. However, the disclosure is not limited thereto, and in other embodiments, the second display area DA2 may have an oval shape or a polygon shape such as a square.

In addition, in an embodiment, the second display area DA2 may include a first stretchable area DA21 and a second stretchable area DA22. The first stretchable area DA21, which is an area having a constant elongation, may be in a center portion of the second display area DA2. In an embodiment, the first stretchable area DA21 may have a circular shape. In another embodiment, the first stretchable area DA21 may be formed as an oval shape or a polygon shape such as a square. Hereinafter, for convenience of explanation, a case in which the first stretchable area DA21 is circular will be mainly described.

The second extension area DA22 may be arranged to surround the first extension area DA21 and may be at a circumference of the second display area DA2. The second stretchable area DA22 may have a closed-loop shape, and when the first stretchable area DA21 has a circular shape, the second stretchable area DA22 may have a ring shape surrounding the circular shape. That is, an outer circumference of the first stretchable area DA21 and an outer circumference of the second stretchable area DA22 may be concentric circles having the same center. The second stretchable area DA22 may include an area having an elongation according to positions. In an embodiment, the elongation of the second stretchable area DA22 may decrease away from the first stretchable area DA21, particularly from a center of the first stretchable area DA21. For example, when an elongation of the first stretchable area DA21 is about 30% and the elongation of the first display area DA1, which may be rigid, is about 0%, the elongation of the second stretchable area DA22 may decrease from 30% to 0% in a radius direction. In other words, a portion of the second stretchable area DA22 adjacent to the first stretchable area DA21 may have an elongation substantially identical to the elongation of the first stretchable area DA21. In addition, a portion of the second stretchable area DA22 adjacent to the first display area DA1 may have an elongation substantially identical to the elongation of the first display area DA1. In an embodiment, the elongation of the second stretchable area DA22 may linearly decrease in the radius direction, but is not limited thereto. It may be understood that, in other embodiments, the elongation of the second stretchable area DA22 may non-linearly decrease, e.g., exponentially or logarithmically, in the radius direction.

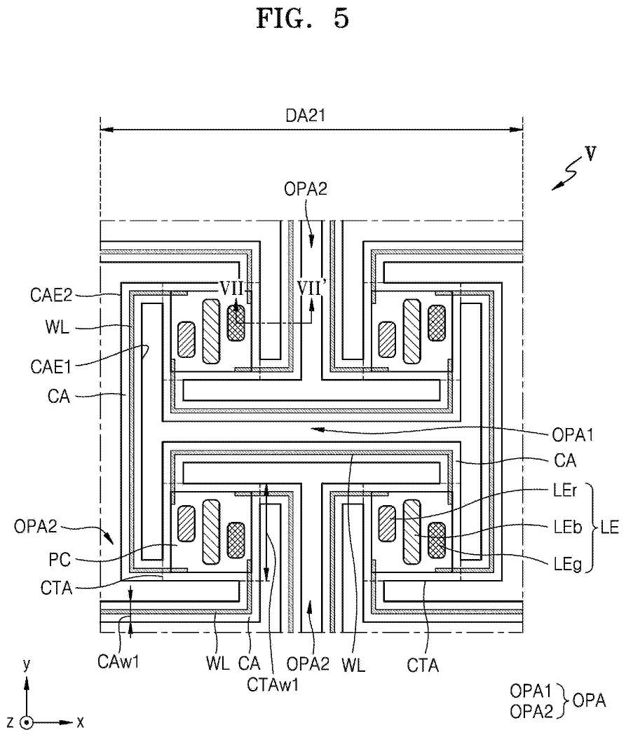

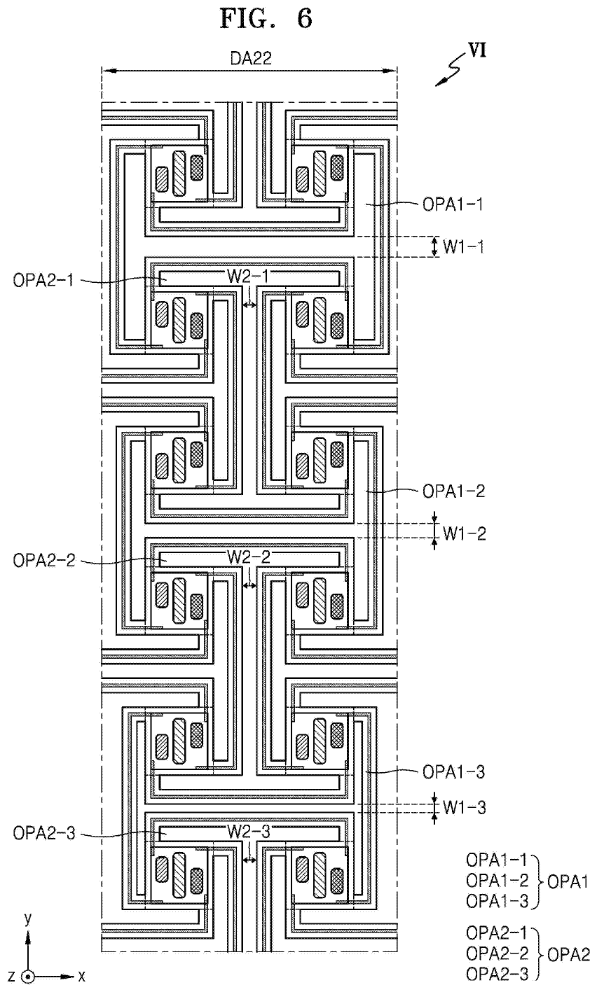

FIG. 5 is a top-plan view schematically illustrating the first stretchable area DA21 according to an embodiment of the disclosure, illustrating an enlarged image of a region V shown in FIG. 4. FIG. 6 is a top-plan view schematically illustrating the second stretchable area DA22 according to an embodiment of the disclosure, illustrating an enlarged image of a region VI shown in FIG. 4.

Referring to FIG. 5, in the first stretchable area DA21 of the second display area DA2, the display panel 10 may include a plurality of island portions CTA, a plurality of connectors CA, and a plurality of openings OPA.

An island portion CTA is an area in which the light-emitting diode LE is arranged, and the plurality of island portions CTA may be arranged apart from one another. In some embodiments, FIG. 5 illustrates that a red light-emitting diode LEr, a green light-emitting diode LEg, and a blue light-emitting diode LEb are arranged in each island portion CTA. In an embodiment, the island portion CTA may have a square shape when seen from top, but the disclosure is not limited thereto.

A connector CA may extend between the island portions CTA adjacent to each other. The connector CA may connect the island portions CTA adjacent to each other. For example, FIG. 5 illustrates that each island portion CTA is connected to four connectors CA. Four connectors CA connected to one island portion CTA may extend in different directions, respectively, and each of the connectors CA may be connected to another island portion CTA adjacent to the one island portion CTA described above. For example, one island portion CTA may be connected, through four connectors CA, to four island portions CTA arranged in a direction surrounding the one island portion CTA described above. The island portions CTA adjacent to each other and the connector CA may be integrally connected to each other.

Each connector CA may extend in a longitudinal direction of the connector CA to connect the island portions CTA adjacent to each other on a plane. Each connector CA may be bent. For example, any one connector CA shown in FIG. 5 may be bent from the second direction (e.g. the y direction or the −y direction) in the first direction (e.g., the x direction or the −x direction) and then may be bent in a reverse second direction (e.g., the −y direction or the +y direction). Another connector CA may be bent from the first direction (e.g. the x direction or the −x direction) in the second direction (e.g., the y direction or the −y direction) and then may be bent in a reverse first direction (e.g., the −x direction or the +x direction). Although FIG. 5 illustrates that a corner of a bent portion of the connector CA has a right angle, in another embodiment, the bent portion of the connector CA may have various angles. In another embodiment, the bent portion of the connector CA may have a rounded shape.

A direction in which the connector CA is bent may indicate the longitudinal direction of the connector CA. The connector CA may have a width Caw1 that is less than a length of elongation between the island portions CTA adjacent to each other. The width Caw1 of the connector CA may be less than a width CTAw1 of the island CTA. A length of the connector CA may be defined as a value obtained by dividing a sum of lengths of a first edge CAE1 and a second edge CAE2 of the connector CA by two, and the width Caw1 of the connector CA indicates a value in a direction perpendicular to the length of the connector CA. The first edge CAE1 of the connector CA may indicate an edge relatively adjacent to the island portion CTA, and the second edge CAE2 may indicate an edge opposite the first edge CAE1 and relatively far from the island portion CTA. In other words, the first edge CAE1 of the connector CA may indicate an edge relatively adjacent to the island portion CTA with reference to a wiring WL, and the second edge CAE2 may indicate an edge relatively far from the island portion CTA with reference to the wiring WL.

Each connector CA may include the wiring WL. The wiring WL may be electrically connected to the subpixel circuit PC in each of the island portions CTA at opposite end portions of a corresponding connector CA. The wiring WL may include a signal line or a voltage line configured to provide a signal or a voltage to the subpixel circuit PC connected to the wiring WL. A width of the wiring WL may be smaller than the width Caw1 of the connector CA.

Although FIG. 5 illustrates that each connector CA includes one wiring WL, the disclosure is not limited thereto. As another embodiment, each connector CA may include a plurality of wirings WL.

The openings OPA may include a kind of through-holes penetrating the display panel 10. Each opening OPA may be surrounded by four island portions CTA and four connectors CA. For example, each opening portion OPA may be surrounded by a side of each of the four island portions CTA and a side of each of the four connectors CA, and on a plane (i.e., in a top-plan view), may have a shape obtained by rotating the letter “H” by about 90 degrees or a shape like the letter “H”.

The openings OPA may be apart from each other. In an embodiment, FIG. 5 illustrates that opening portions (hereinafter, referred to as first opening portion OPA1) having the shape obtained by rotating the letter “H” by about 90 degrees and opening portions (hereinafter, referred to as second opening portion OPA2) having the shape like the letter “H” are alternately arranged in the +x directions and the ty directions. In the specification, the opening OPA may indicate a first opening OPA and/or a second opening OPA2. That is, each opening OPA may include three lines, which make the letter “H” together, and each of the three lines may have the same width when a force is not applied to the first stretchable area DA21.

When a force is applied to the display apparatus 1, more specifically, to the display panel 10, as the shape of the opening OPA, i.e., the first opening OPA1 and/or the second opening OPA2, changes, the display apparatus 1 that is stretchable may be implemented. In addition, occurrence of a stress during transformation of the display apparatus 1 may be easily reduced, and by doing so, abnormal transformation of the display apparatus 1 may be prevented, and the durability of the display apparatus 1 may be effectively improved.

Referring to FIG. 6, in the second stretchable area DA22 of the second display area DA2, the display panel 10 may include island portions CTA, connectors CA, and openings OPA, like in the first stretchable area DA21. Hereinafter, the second stretchable area DA22 will be described mainly based on differences from the first stretchable area DA21.

As shown in FIG. 6, in the second stretchable area DA22, the first openings OPA1 and the second openings OPA2 may be alternately arranged in a radius direction (here, a y direction). For example, a plurality of first openings OPA1 may be referred to as a 1-1 opening OPA1-1, a 1-2 opening OPA1-2, and a 1-3 opening OPA1-3, respectively. In addition, a plurality of second openings OPA2 may be referred to as a 2-1 opening OPA2-1, a 2-2 opening OPA2-2, and a 2-3 opening OPA2-3, respectively. The 1-1 opening OPA1-1, the 1-2 opening OPA1-2, and the 1-3 opening OPA1-3 and the 2-1 opening OPA2-1, the 2-2 opening OPA2-2, and the 2-3 opening OPA2-3 may be alternately arranged. That is, the 1-1 opening OPA1-1, the 2-1 opening OPA2-1, the 1-2 opening OPA1-2, the 2-2 opening OPA2-2, the 1-3 opening OPA1-3, and the 2-3 opening OPA2-3 may be sequentially arranged in a radius direction.

In this case, according to an embodiment, a width of the first openings OPA1 having the shape approximately like the letter “H” may decrease in the radius direction. That is, the width of the first openings OPA1 may decrease away from the first stretchable area DA21, more particularly, a center of the first stretchable area DA21. More particularly, a width w1-1 of the 1-1 opening OPA1-1 may be greater than a width w1-2 of the 1-2 opening OPA1-2, and the width w1-2 of the 1-2 opening OPA1-2 may be greater than a width w1-3 of the 1-3 opening OPA1-3.

Here, in an embodiment, a width of the second openings OPA2 obtained by rotating the letter “H” by about 90 degrees may be identical, as shown in FIG. 6. However, in another embodiment, the width of the second openings OPA2 may also decrease in the radius direction. That is, the width of the second openings OPA2 may decrease away from the first stretchable area DA21, more particularly, the center of the first stretchable area DA21. More particularly, a width w2-1 of the 2-1 opening OPA2-1 may be greater than a width w2-2 of the 2-2 opening OPA2-2, and the width w2-2 of the 2-2 opening OPA2-2 may be greater than a width w2-3 of the 2-3 opening OPA2-3.

In this case, the width w1-1 of the 1-1 opening OPA1-1 may be identical to the width w2-1 of the 2-1 opening OPA2-1, the width w1-2 of the 1-2 opening OPA1-2 may be identical to the width w2-2 of the 2-2 opening OPA2-2, and the width w1-3 of the 1-3 opening OPA1-3 may be identical to the width w2-3 of the 2-3 opening OPA2-3. However, in another embodiment, the widths of the 1-1 opening OPA1-1, the 2-1 opening OPA2-1, the 1-2 opening OPA1-2, the 2-2 opening OPA2-2, the 1-3 opening OPA1-3, and the 2-3 opening OPA2-3 may sequentially decrease in the radius direction.

Hereinafter, for convenience of explanation, a case in which the widths of the first openings OPA1 decrease in the radius direction and the widths of the second openings OPA2 are constant will be mainly described. In an embodiment, the widths of the first openings OPA1 may linearly decrease. That is, a decrease rate of the widths of the 1-1 opening OPA1-1, the 1-2 opening OPA1-2, and the 1-3 opening OPA1-3 may be linear. As another embodiment, the width of the first openings OPA1 may exponentially or logarithmically decrease.

According to one or more embodiments of the disclosure, the display panel 10 may be rigid in the first display area DA1 and stretchable in the second display area DA2. In addition, the display panel 10 may have a constant elongation in the first stretchable area DA21 of the second display area DA2, and may have an elongation decreasing toward the radius direction in the second stretchable area DA22. Like in the following description, when a text is input, a display screen of the display apparatus 1 may be touched and pressed such that the display panel 10 touches a board layer 30, particularly a convex portion 31, under the display panel 10. By doing so, through the convex portion 31 of the board layer 30, texts may be accurately input, and a sense of touch during input of the texts may also be improved.

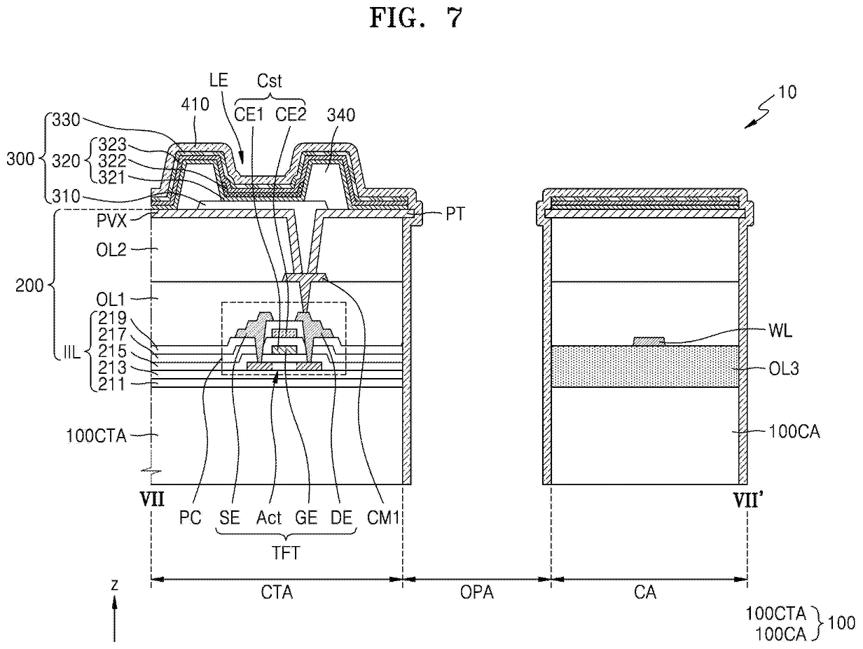

FIG. 7 is a cross-sectional view of the display apparatus 1 according to an embodiment of the disclosure, taken along line VII-VII′ shown in FIG. 5. For convenience of explanation, FIG. 7 illustrates the display panel 10 of the display apparatus 1, and hereinafter, a cross-section of the display panel 10 will be mainly described.

Referring to FIG. 7, in the first stretchable area DA21, the display panel 10 may include the substrate 100, the circuit layer 200, and the light-emitting diode layer 300. In the first extension area DA21, the display panel 10 may have a structure similar to the stack structure of the display panel 10 in the first display area DA1 described with reference to FIG. 3. Hereinafter, some of descriptions of same components will be omitted, and the embodiments will be briefly described.

The display panel 10 may include the substrate 100. The substrate 100 may include a high-molecular resin such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be provided in a single-layer structure. For example, the substrate 100 may be provided in the single-layer structure having a small thickness. As the substrate 100 is provided in a small thickness, flexibility of the display apparatus 1 including the substrate 100 may be improved. In another embodiment, the substrate 100 may include a multiple-layer structure including a base layer including the aforementioned high-molecular resin and a barrier layer including an inorganic insulating layer. The substrate 100 including the high-molecular resin may be flexible, rollable, and bendable. In some embodiments, the substrate 100 may include glass.

The inorganic insulating layer IIL and the subpixel circuit PC may be disposed on the substrate 100 of the island portion CTA. In this case, the inorganic insulating layer IIL and the subpixel circuit PC may be not disposed on the substrate 100 of the connector CA.

The barrier layer 211 may be disposed on the substrate 100 of the island portion CTA. The barrier layer 211 may include a single layer or multiple layers including an inorganic material such as silicon nitride, silicon oxide, and/or silicon oxynitride. The buffer layer 213 may be disposed on the barrier layer 211 of the island portion CTA. The buffer layer 213 may include a single layer or multiple layers including an inorganic material such as silicon nitride, silicon oxide, and/or silicon oxynitride.

The semiconductor layer Act may be disposed on the buffer layer 213. The semiconductor layer Act may include polysilicon. Alternatively, the semiconductor layer Act may include amorphous silicon, an oxide semiconductor, or an organic semiconductor. In an embodiment, the semiconductor layer Act may include: a channel area; and a source area and a drain area arranged at opposite sides of the channel area, respectively.

The first gate insulating layer 215 may be disposed on the semiconductor layer Act and the buffer layer 213. The first gate insulating layer 215 may include an inorganic insulating material such as silicon oxide, silicon nitride, silicon oxynitride, aluminum oxide, titanium oxide, tantalum oxide, hafnium oxide, or zinc oxide. The zinc oxide may include zinc oxide (ZnO) and/or zinc peroxide (ZnO₂).

The gate electrode GE may be disposed on the first gate insulating layer 215. The gate electrode GE may overlap the channel area of the semiconductor layer Act in a top-plan view. The gate electrode GE may include a low-resistance metal material. In an embodiment, the gate electrode GE may include a conductive material including Mo, Al, Cu, Ti, and the like, and may include multiple layers or a single layer including the aforementioned materials.

The second gate insulating layer 217 may be disposed on the gate electrode GE and the first gate insulating layer 215. The second gate insulating layer 217 may include an inorganic insulating material such as silicon nitride, silicon oxide, and/or silicon oxynitride.

The second capacitor electrode CE2 may be disposed on the second gate insulating layer 217. The second capacitor electrode CE2 may overlap the gate electrode GE in a top-plan view. In this case, the gate electrode GE may function as the first capacitor electrode CE1. Although FIG. 7 illustrates that the storage capacitor Cst and the transistor TFT overlap each other in a top-plan view, in another embodiment, the storage capacitor Cst and the transistor TFT may not overlap each other in a top-plan view. In this case, the first capacitor electrode CE1 and the gate electrode GE may be separate electrodes. The second capacitor electrode CE2 may include Al, Pt, Pd, Ag, Mg, Au, Ni, Nd, Ir, Cr, Ca, Mo, Ti, W, and/or Cu, and may include a single layer or multiple layers including the aforementioned materials.

The interlayer-insulating layer 219 may be disposed on the second capacitor electrode CE2 and the second gate insulating layer 217. The interlayer-insulating layer 219 may include an inorganic insulating material such as silicon oxide, silicon nitride, silicon oxynitride, and the like.

The source electrode SE and the drain electrode DE may each be disposed on the interlayer-insulating layer 219. The source electrode SE and the drain electrode DE may each be connected to the semiconductor layer Act through the contact holes provided in the first gate insulating layer 215, the second gate insulating layer 217, and the interlayer-insulating layer 219. At least one of the source electrode SE and the drain electrode DE may include a conductive material including Mo, Al, Cu, and Ti, and may be provided as multiple layers or a single layer including the aforementioned materials. In an embodiment, at least one of the source electrode SE and the drain electrode DE may include the multiple-layer structure including Ti/Al/Ti.

As described above, the inorganic insulating layer IIL may be not disposed on the substrate 100 of the connector CA. The connector CA may not include the inorganic insulating layer IIL in which cracks relatively easily occur, and therefore, during extension and contraction of the second display area DA2, damage to the connector CA transformed in a relatively high degree may be prevented.

A third organic insulating layer OL3 may be disposed on the substrate 100 of the connector CA. A difference in height may be minimized by the third organic insulating layer OL3 when the wiring WL extends from the island portion CTA to the connector CA. The third organic insulating layer OL3 may absorb a stress that may be applied to the wiring WL. The third organic insulating layer OL3 may include an organic material. The third organic insulating layer OL3 may include an organic insulating material, e.g., a general-purpose polymer such as PMMA or PS, a polymer derivative having a phenolic group, an acryl-based polymer, an imide-based polymer, an aryl ether-based polymer, an amide-based polymer, a fluoride-based polymer, a p-xylene-based polymer, a vinyl alcohol-based polymer, and blends thereof.

The wiring WL may be disposed on the third organic insulating layer OL3. The wiring WL may extend from the island portion CTA to the connector CA. Although not shown in FIG. 7, the wiring WL may be electrically connected to the subpixel circuit PC. Through the wiring WL, the subpixel circuit PC of one island portion CTA may be electrically connected to the subpixel circuit PC of another island portion CTA adjacent to the island portion CTA. The wiring WL may include a conductive material including Mo, Al, Cu, Ti, and may include multiple layers or a single layer including the aforementioned materials. In an embodiment, the wiring WL may have a multiple-layer structure including Ti/Al/Ti. In an embodiment, the wiring WL may be formed through the same process in which the source electrode SE and the drain electrode DE are formed.

In addition, the wiring WL may be disposed between the third organic insulating layer OL3 and the first organic insulating layer OL1. When the second display area DA2 elongates, the connector CA may be transformed. In this case, a stress neutral plane may be on the display panel 10. The wiring WL is disposed between the third organic insulating layer OL3 and the first organic insulating layer OL1, and thus may be on the stress neutral plane, and the stress applied to the wiring WL may be minimized.

The first organic insulating layer OL1 may be disposed on the inorganic insulating layer IIL, the source electrode SE, and the drain electrode DE. In addition, the first organic insulating layer OL1 may be arranged to cover the third organic insulating layer OL3 and the wiring WL. The first organic insulating layer OL1 may include an organic material. The first organic insulating layer OL1 may include an organic insulating material, e.g., a general-purpose polymer such as PMMA or PS, a polymer derivative having a phenolic group, an acryl-based polymer, an imide-based polymer, an aryl ether-based polymer, an amide-based polymer, a fluoride-based polymer, a p-xylene-based polymer, a vinyl alcohol-based polymer, and a blend thereof.

The first contact electrode CM1 may be disposed on the first organic insulating layer OL1. The first contact electrode CM1 may be electrically connected to the subpixel circuit PC through a contact hole in the first organic insulating layer OL1. The first contact electrode CM1 may include a conductive material including Mo, Al, Cu, Ti, and may include multiple layers or a single layer including the aforementioned materials. The first contact electrode CM1 may include the multiple-layer structure including Ti/Al/Ti.

The second organic insulating layer OL2 may be disposed on the first organic insulating layer OL1 and the first contact electrode CM1. The second organic insulating layer OL2 may include an organic material. The second organic insulating layer OL2 may include an organic insulating material, e.g., a general-purpose polymer such as PMMA or PS, a polymer derivative having a phenolic group, an acryl-based polymer, an imide-based polymer, an aryl ether-based polymer, an amide-based polymer, a fluoride-based polymer, a p-xylene-based polymer, a vinyl alcohol-based polymer, and a blend thereof.

An inorganic layer PVX may be disposed on the second organic insulating layer OL2. The inorganic layer PVX may include an inorganic material. In an embodiment, the inorganic layer PVX may include an end portion protruding toward the opening OPA (or protruding toward the connector CA), e.g., a protrusion tip PT.

The light-emitting diode layer 300 may be disposed on the circuit layer 200. The light-emitting diode layer 300 may include the light-emitting diode LE and a bank layer 340. The light-emitting diode LE may include an organic light-emitting diode. The light-emitting diode LE may include a first electrode 310, an intermediate layer 320, and a second electrode 330 that is a counter electrode.

The first electrode 310 of the light-emitting diode LE may be electrically connected to the first contact electrode CM1 through a contact hole in the second organic insulating layer OL2. The first electrode 310 may include a conductive oxide, e.g., ITO, IZO, ZnO, In₂O₃, IGO, AZO. In another embodiment, the first electrode 310 may include a reflective film including Ag, Mg, Al, Pt, Pd, Au, Ni, Nd, Ir, Cr, or a compound thereof. In another embodiment, the first electrode 310 may further include a film including ITO, IZO, ZnO, or In₂O₃ on/under the aforementioned reflective film.

The bank layer 340 may cover a rim of the first electrode 310. The bank layer 340 may include the emission opening, and the emission opening may overlap the first electrode 310 in a top-plan view. The emission opening may define an emission area of light emitted from the light-emitting diode LE. The bank layer 340 may include an organic insulating material and/or an inorganic insulating material. In some embodiments, the bank layer 340 may include a light-blocking material.

Although not shown, a spacer may be disposed on the bank layer 340. In a method of manufacturing the display panel 10, a mask sheet may be used, and in this case, the mask sheet may enter an opening of the bank layer 340 or may be attached to the bank layer 340. The spacer may prevent defects such as damage or breakage of the substrate 100 and a portion of a multi-layered film on the substrate due to the mask sheet when a deposition material is deposited on the substrate 100.

The intermediate layer 320 may be disposed on the first electrode 310 and the bank layer 340. The intermediate layer 320 may include the emission layer 322. The emission layer 322 may overlap the first electrode 310 in a top-plan view. The emission layer 322 may include a high-molecular or low-molecular material emitting light of certain colors.

The intermediate layer 320 may further include a first function layer 321 and/or a second function layer 323. The first function layer 321 may be disposed between the first function layer 321 and the emission layer 322. The first function layer 321 may include a HTL and/or a HIL. The second function layer 323 may be disposed between the emission layer 322 and the second electrode 330. The second function layer 323 may include an ETL and/or an EIL. In an embodiment, the first function layer 321 and the second function layer 323 may generally overlap the entire surface of the substrate 100 in a top-plan view.

The second electrode 330 may be disposed on the intermediate layer 320. The second electrode 330 may include a conductive material having a small work function. For example, the second electrode 330 may include the (semi) transparent layer including Ag, Mg, Al, Pt, Pd, Au, Ni, Nd, Ir, Cr, Li, Ca, or alloys thereof. Alternatively, the second electrode 330 may further include a layer including ITO, IZO, ZnO, and In₂O₃ on the (semi) transparent layer including the aforementioned material.

The organic material included in the intermediate layer 320, e.g., the first function layer 321 and the second function layer 323, may be discontinuous. The first function layer 321 and the second function layer 323 including the organic material may be used as a path through which oxygen or moisture from outside may permeate. In the present embodiment, as the inorganic layer PVX has the protrusion tip PT protruding toward the opening OPA, the first function layer 321 and the second function layer 323 may be discontinuous. Accordingly, introduction of moisture or oxygen proceeding from outside toward the light-emitting diode LE may be prevented or reduced.

An inorganic encapsulation layer 410 may be disposed on the light-emitting diode layer 300. The inorganic encapsulation layer 410 may generally cover the substrate 100. The inorganic encapsulation layer 410 may include at least one inorganic material among Al₂O₃, TiO₂, Ta₂O₅, HfO₂, ZnO₂, SiO₂, SiNₓ, and SiON. In some embodiments, an organic encapsulation layer may be disposed on the inorganic encapsulation layer 410. Furthermore, additional inorganic encapsulation layers may be further disposed on the organic encapsulation layer.

An opening OPA may be defined between the island portion CTA and the connector CA and between the connectors CA.

Although a cross-section of the first stretchable area DA21 has been mainly described with reference to FIG. 7, the second stretchable area DA22 is generally similar to the first extension area DA21 except the width of the opening OPA, and therefore, descriptions thereof will not be repeatedly given.

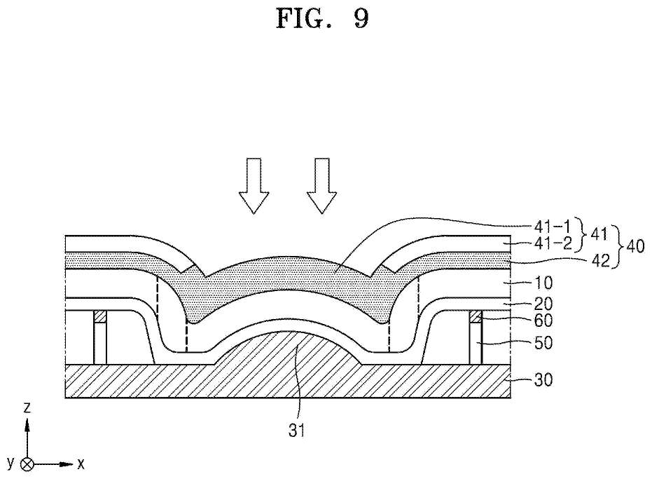

FIG. 8 is a cross-sectional view schematically illustrating a portion of the display apparatus 1 according to an embodiment of the disclosure. FIG. 8 may correspond to a cross-section taken along line VIII-VIII′ shown in FIG. 1. FIG. 9 is a cross-sectional view schematically illustrating a portion of the display apparatus 1 according to an embodiment of the disclosure. FIG. 9 illustrates a case in which the display apparatus 1 shown in FIG. 8 is touched, pressed, and then elongates.

Referring to FIG. 8, the display apparatus 1 may include the display panel 10, an anti-friction layer 20, the board layer 30, and a cover film layer 40.

As described above, the display apparatus 1 may include the first display area DA1 and the second display area DA2. The first display area DA1 and the second display area DA2 may be defined with reference to a top-plan view, and may also be defined with respect to the display panel 10. In other words, it may be considered that the display panel 10 also includes the first display area DA1 and the second display area DA2.

As described above, the display panel 10 may be rigid in the first display area DA1. In the first stretchable area DA21, the display panel 10 may have a constant elongation. In the second stretchable area DA22, the elongation of the display panel 10 may decrease away from a center of the first stretchable area DA21.

The board layer 30 may be arranged at bottom of the display panel 10, i.e., a side opposite to a display surface of the display panel 10. The board layer 30 may include a rigid layer. The board layer 30 may be arranged apart from the display panel 10 in a thickness direction (e.g., a z direction shown in FIG. 8) of the display panel 10.

The board layer 30 may include the convex portion 31. The convex portion 31 may include a portion protruding from a plane of the board layer 30 toward the display panel 10. When seen from top, the convex portion 31 may be arranged to overlap the second display area DA2 of the display panel 10 in a top-plan view and may protrude toward the second display area DA2. In an embodiment, the convex portion 31 may be protrude in the form of a curve. The convex portion 31 may also be arranged apart from the display panel 10 in the thickness direction of the display panel 10.

For input of texts, an image of buttons, e.g., alphabets, may be displayed on the second display area DA2 of the display panel 10. A user may touch and press the button image displayed in the second display area DA2, and in this case, the display panel 10 may elongate from the second display area DA2 and contact the board layer 30, particularly the convex portion 31. However, like in the following descriptions, when the anti-friction layer 20 is attached to the display panel 10, the anti-friction layer 20 may contact the board layer 30, particularly the convex portion 31. By doing so, the user touching and pressing the button image may have a sense of touch like inputting using physical keyboard despite of touching and pressing the image on the display surface. By doing so, positions of buttons may be accurately identified for inputting texts, and thus, accuracy in inputting texts and the sense of touch may be improved. In addition, as the convex portion 31 and the display panel 10 are arranged apart from each other and the convex portion 31 may be identified only when the button image is touched and pressed, images may be continuously displayed without curves or protrusion of the display surface in general occasions without text inputs (e.g., an occasion in which images are merely displayed).

In an embodiment, in a top-plan view, the convex portion 31 may have a shape identical to a shape of the first stretchable area DA21 of the display panel 10, e.g., a circular shape. In this case, the convex portion 31 may have a radius smaller than a radius of the first stretchable area DA21. In other words, in a top-plan view, an outer circumference of the convex portion 31 may be within an outer circumference of the first stretchable area DA21. Like this, the first stretchable area DA21 of the display panel 10 may be on the convex portion 31 to completely cover the convex portion 31, and therefore, as shown in FIG. 9, when the display panel 10 elongates toward the convex portion 31, the display panel 10 may completely cover the convex portion 31 along curves of the convex portion 31. Here, due to the second stretchable area DA22 of the display panel 10, the display panel 10 may flexibly elongate from the outer circumference of the first stretchable area DA21 elongating along the curves of the convex portion 31 to the first stretchable area DA21 that is rigid.

The anti-friction layer 20 may be disposed under the display panel 10. The anti-friction layer 20 may include a layer for minimizing a friction when the anti-friction layer 20 contacts the board layer 30. When the anti-friction layer 20 contacts the board layer 30 with a great friction, in a case where the display panel 10 elongates toward the convex portion 31, a stress may be concentrated to a portion of the display panel 10 overlapping an edge portion of the convex portion 31 in a top-plan view. Accordingly, the anti-friction layer 20 may include a material having a small coefficient of friction to minimize a friction with the board layer 30. The anti-friction layer 20 may be disposed over a bottom surface of the display panel 10.

A gap supporter 50 may be disposed between the anti-friction layer 20 and the board layer 30. The gap supporter 50 may support the display panel 10 and the anti-friction layer 20 while maintaining a gap between the board layer 30 and the anti-friction layer 20 such that the board layer 30 may be arranged apart from the display panel 10 and the anti-friction layer 20. In an embodiment, the gap supporter 50 may be arranged between every two convex portions 31. In a top plan view, the gap supporter 50 may be disposed outside the second display area DA2, i.e., in the first display area DA1. Alternatively, in another embodiment, the gap supporter 50 may be arranged to surround the second display area DA2. In a top-plan view, the gap supporter 50 may be arranged as a closed-loop surrounding the outer circumference of the second display area DA2.

In addition, the gap supporter 50 may be attached to the anti-friction layer 20 by an attachment portion 60. The attachment portion 60 may be disposed between the gap supporter 50 and the anti-friction layer 20 and/or between the gap supporter 50 and the board layer 30.

The cover film layer 40 may be disposed on the display panel 10. The cover film layer 40 may protect the display panel 10 from external impacts and the like, and may elongate to correspond to elongation of the display panel 10. The cover film layer 40 may include an elastomer material. Furthermore, in an embodiment, the cover film layer 40 may include a first cover film layer 41 and a second cover film layer 42, i.e., a layer disposed under the first cover film layer 41.

The first cover film layer 41 may include a first film portion 41-1 and a second film portion 41-2. The first film portion 41-1 may be arranged to overlap the second display area DA2, particularly the first stretchable area DA21, in a top-plan view. In an embodiment, the first film portion 41-1 may have a shape identical to a shape of the first stretchable area DA21, e.g., a circular shape. In this case, the first film portion 41-1 may have a radius smaller than the radius of the first stretchable area DA21. In other words, in a top-plan view, an outer circumference of the first film portion 41-1 may be within the outer circumference of the first extension area DA21. Furthermore, in an embodiment, the first film portion 41-1 may have a radius greater than a radius of the convex portion 31. In other words, in a top-plan view, the outer circumference of the first film portion 41-1 may be outside the outer circumference of the convex portion 31.

The second film portion 41-2 may be arranged to surround the first film portion 41-1. The second film portion 41-2 may include a portion surrounding a plurality of the first film portion 41-1 on the first cover film layer 41. In a top-plan view, the second film portion 41-2 may overlap the first display area DA1. That is, it may be understood that the second film portion 41-2 has a plurality of openings and the first film portion 41-1 is arranged in each of the plurality of openings.

In an embodiment, the first film portion 41-1 and the second film portion 41-2 may include materials having different moduli, respectively. For example, the first film portion 41-1 may have a first modulus, and the second film portion 41-2 may have a second modulus. Here, the first modulus may be less than the second modulus. That is, the first film portion 41-1 corresponding to the second display area DA2 being stretchable may have a relatively less modulus, and thus may be flexible to correspond to elongation of the display panel 10 in the second display area DA2. The second film portion 41-2 corresponding to the first display area DA1, which is rigid, may have a relatively greater modulus, and thus may focus on protection of the display panel 10.

Like this, the first film portion 41-1 having a smaller modulus is arranged to overlap the first elongating DA21 and the convex portion 31 in a top-plan view, and the outer circumference of the first film portion 41-1 is disposed between the outer circumference of the first stretchable area DA21 and the outer circumference of the convex portion 31. Accordingly, the display panel 10 and the cover film layer 40 may cover the convex portion 31 even when touched, pressed, and extends, and concentration of the strength on the portion of the display panel 10 overlapping the edge portion of the convex portion 31 in a top-plan view may be effectively prevented.

The second cover film layer 42 may be disposed between the first cover film layer 41 and the display panel 10, and may be disposed over an entire surface of the display panel 10. In an embodiment, the second cover film layer 42 may include a material identical to a material of the first film portion 41-1. In this case, the second cover film layer 42 and the first film portion 41-1 may be integrally formed (i.e., monolithic). In this case, the first film portion 41-1 may have a shape protruding in a circular shape from the second cover film layer 42. The second cover film layer 42 may have a small modulus like the first film portion 41-1, and thus may provide flexibility on the entire surface of the display panel 10.

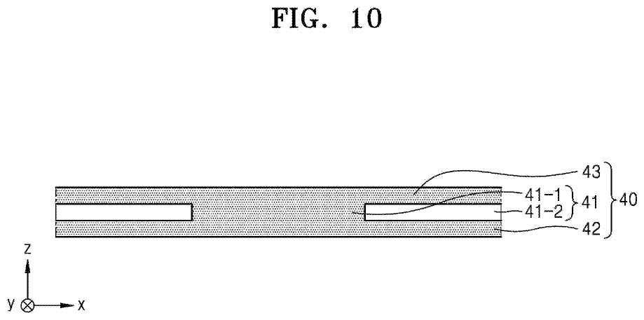

FIGS. 10 to 12 are each a cross-sectional view schematically illustrating the cover film layer 40 according to an embodiment of the disclosure. For convenience of explanation, FIGS. 10 to 12 only illustrate the cover film layer 40. Hereinafter, only differences from the cover film layer 40 described above will be mainly described.

Referring to FIG. 10, the cover film layer 40 may further include a third cover film layer 43 disposed on the first cover film layer 41. The third cover film layer 43 may be disposed on the entire surface of the first cover film layer 41. In an embodiment, the third cover film layer 43 may include a material identical to a material of the first film portion 41-1. In this case, the third cover film layer 43 may include a material identical to the material of the first film portion 41-1. In this case, the third cover film layer 43 and the first film portion 41-1 may be integrally formed (i.e., monolithic). The third cover film layer 43 may have a small modulus like the first film portion 41-1, and thus may provide flexibility on the entire surface of the display panel 10.

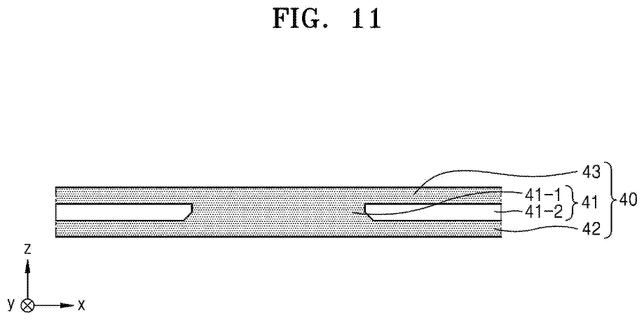

Referring to FIG. 11, the outer circumference of the first film portion 41-1 may be tapered to decrease toward top of the thickness direction (e.g., the z direction shown in FIG. 11) of the display panel 10. That is, in the first film portion 41-1, a radius of the top may be smaller than a radius of the bottom. Accordingly, when the display panel 10 and the cover film layer 40 are pressed and contact the convex portion 31, the first film portion 41-1 may elongate along a convex surface of the convex portion 31 and contact the convex portion 31. By doing so, concentration of a stress at the portion of the display panel 10 overlapping the edge portion of the convex portion 31 in a top-plan view may be effectively prevented.

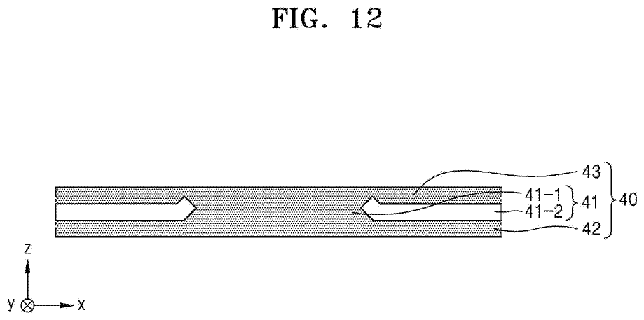

Referring to FIG. 12, in an embodiment, an end of the second film portion 41-2, which defines an outer circumference of the first film portion 41-1, may be bent toward the top of the thickness direction of the display panel 10. A degree by which the circumference of the second film portion 41-2 is bent may be in a direction substantially identical to a direction of an inclination of the convex surface of the convex portion 31. For example, the degree by which the circumference of the second film portion 41-2 is bent may be substantially identical to a degree of a tangent line at a point of the convex portion 31. Even in this case, concentration of the stress on the portion of the display panel 10 overlapping the edge portion of the convex portion 31 in a top-plan view may be effectively prevented.

According to embodiments of the disclosure, in a display apparatus where a front surface displays images, text input buttons may be implemented to improve accuracy in text input and a sense of touch in text input.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising, in a top-plan view, a first display area and one or more second display areas surrounded by the first display area, wherein the one or more second display areas are stretchable,
wherein the second display area comprises a first stretchable area having a constant stretching rate and a second stretchable area surrounding the first stretchable area and having a stretching rate decreasing away from a center of the first stretchable area.

2. The display apparatus of claim 1,
wherein, in the second display area,
the display panel comprises island portions apart from one another, connectors connecting the island portions to one another, and openings surrounded and defined by the island portions and the connectors.

3. The display apparatus of claim 2, wherein a subpixel configured to emit at least one of red light, blue light, and green light is arranged in each of the island portions.

4. The display apparatus of claim 2, wherein the openings in the first stretchable area have a same width.

5. The display apparatus of claim 2, wherein the openings in the second stretchable area have different widths.

6. The display apparatus of claim 5, wherein the widths of the openings in the second stretchable area decrease away from a center of the first stretchable area.

7. The display apparatus of claim 1, wherein, in the top-plan view, the second stretchable area has a closed-loop shape.

8. The display apparatus of claim 1, wherein the one or more second display areas are arranged in parallel in a first direction.

9. The display apparatus of claim 1, further comprising a board layer arranged under the display panel, and
the board layer comprises a convex portion overlapping the second display area in the top-plan view and protruding in a convex manner toward the display panel.

10. The display apparatus of claim 9, wherein the board layer is arranged apart from the display panel in a thickness direction.

11. The display apparatus of claim 10, further comprising a gap supporter surrounding the convex portion in the top-plan view and filling a gap between the display panel and the board layer.

12. The display apparatus of claim 9,
wherein, in the top-plan view, the convex portion is arranged such that an outer circumference of the convex portion is within an outer circumference of the first stretchable area.

13. The display apparatus of claim 9, further comprising an anti-friction layer disposed between the display panel and the board layer.

14. The display apparatus of claim 1, further comprising a first cover film layer disposed on the display panel,
wherein the first cover film layer comprises a first film portion having a first modulus and overlapping the second display area in the top-plan view and a second film portion having a second modulus and surrounding the first film portion in the top-plan view.

15. The display apparatus of claim 14, wherein the first modulus of the first film portion is less than the second modulus of the second film portion.

16. The display apparatus of claim 14, further comprising a board layer disposed under the display panel,
wherein the board layer comprises a convex portion overlapping the second display area in the top-plan view and protruding in a convex manner toward the display panel, and
in the top-plan view, an outer circumference of the first film portion is between an outer circumference of the first stretchable area and an outer circumference of the convex portion.

17. The display apparatus of claim 14, further comprising a second cover film layer disposed between the first cover film layer and the display panel,
wherein the second modulus is the same as the first modulus,
wherein the second cover film layer and the first film portion are monolithic.

18. The display apparatus of claim 17, further comprising a third cover film layer disposed on the first cover film layer and having the first modulus,
wherein the third cover film layer and the first film portion are monolithic,
wherein a cover film layer is defined to include the first cover film layer, the second cover film layer, and the third cover film layer.

19. The display apparatus of claim 18, wherein an outer circumference of the first film portion is tapered and decreases toward a top of the cover film layer.

20. The display apparatus of claim 18, wherein an end of the second film portion, defining an outer circumference of the first film portion, is bent toward a top of the cover film layer in a thickness direction.
